(19) United States
(12) Patent Application Publication
(10) Pub. No.: US 2026/0280115 A1
(43) Pub. Date: Sep. 17, 2026

(54) CONNECTION ASSEMBLY, HOUSING AS WELL AS ANTENNA

(71) Applicant: Telefonaktiebolaget LM Ericsson (publ), Stockholm (SE)

(72) Inventor: Thomas Haunberger, Bad Reichenhall (DE)

(21) Appl. No.: 19/119,168

(22) PCT Filed: Nov. 9, 2022
(86) PCT No.: PCT/EP2022/081249

§ 371 Date: Apr. 8, 2025

(51) Int. Cl. H01Q 1/52; H01Q 1/36

(52) U.S. Cl. CPC H01Q 1/521; H01Q 1/362

(57) ABSTRACT

A connection assembly has a first structural component, a second structural component and a contacting element. A first connection section and a second connection section of the structural components face each other, forming a slot between them. The first structural component comprises a groove in the first connection section, the groove being confined at least by two straight walls. The contacting element comprises a contacting portion being a helix, the contacting portion being in physical contact with the second connection section of the second structural component and with the straight walls of the first structural component. Further, a housing and an antenna are shown.

### TECHNICAL FIELD

The invention relates to a connection assembly, a housing with such a connection assembly as well as an antenna with such a connection assembly.

### BACKGROUND

In systems involving high-frequency electromagnetic radiation, in particular in antennas, passive intermodulation (PIM) between structural components subjected to electromagnetic radiation is problematic. In particular cases where certain sensible parts have to be shielded against electromagnetic radiation, PIM is likely to occur when connecting two structural components. For example, the electronics of an active antenna may have to be shielded from the radiation of passive radiators located close by.

Known solutions, however, are expensive as they need specialized parts or specialized materials to avoid PIM at the connection of two structural components.

### SUMMARY

It is thus an object of the invention to provide a connection assembly that avoids or alleviates passive intermodulation reliably and at low costs.

For this purpose, an embodiment relates to a connection assembly, having a first structural component, a second structural component and a contacting element for providing a galvanic connection between the first structural component and the second structural component. The first structural component comprises a first connection section and the second structural component comprises a second connection section, the first connection section and the second connection section facing each other, forming a slot between them. The first structural component comprises a groove in the first connection section open towards the second connection section, wherein the groove extends in a longitudinal direction of the slot and is confined at least by two straight walls. The contacting element comprises a contacting portion being a helix, the contacting portion extending in the longitudinal direction of the slot and being in physical contact with the second connection section of the second structural component and in physical contact with the straight walls of the first structural component.

By providing a groove with two straight walls and a helical contacting element, the contacting element has well-defined contact points at the straight walls of the first structural component and also at the second structural component, in particular at straight walls of the second structural component. Thus, due to the well-defined contact points, PIM is avoided or alleviated reliably. At the same time, due to the simple form of the contacting element, the connection assembly is cost-efficient.

The straight walls are for example angled with respect to each other, in particular with an angle larger than 0° and smaller than 90°.

The groove may have a V-shaped cross section.

The direction of extension of the contacting portion is the direction of the axis of the helix.

The helix may have a constant or a varying radius and/or pitch along its axis, i.e. in longitudinal direction.

The first structural component and/or the second structural component may be made of electrically conducting material, e.g. steel or aluminum, or may have an electrically conductive surface.

For providing reliable contact, the contacting element, in particular the contacting portion may extend partially in the groove and partially in the slot and/or the contacting portion, in particular the helix, is radially elastic.

For example, the contacting portion, in particular the helix, may be radially elastic.

In an aspect, the pitch of the helix is smaller than one quarter of a wavelength of a design frequency of the connection assembly. This way, the distance between the contact points is also smaller than one quarter of the wavelength, reliably avoiding or alleviating PIM laterally between two contact points.

In an embodiment, the contacting element has two end portions, wherein the contacting portion is located between the two end portions, wherein the two end portions extend from the contacting portion radially inwards, avoiding accidental contact of the two end portions with one of the structural components.

The end portions may merge with the contacting portion.

For a cost-efficient contacting element, the contacting element may be made of a single piece, in particular a wire.

In an aspect, the contacting element has a surface made of an electrically conducting material, in particular aluminum, brass, silver, tin, copper and/or bronze, thus providing optimal electric conductivity for avoiding PIM.

The contacting element may be made fully of electrically conducting material or has a surface coating of electrically conducting material.

For example, the first connection section is parallel to the second connection section leading to a simple assembly of the connection assembly.

In an embodiment, the connection assembly comprises a fixation extending transversely through the slot and fixing the first structural component to the second structural component, in particular wherein the fixation is located inwards of the contacting element with respect to a depth direction of the slot. Thus way, the fixation assembly also provides mechanical fixation of the structural components.

The fixation may be a screw connection or a bolted connection.

For providing sealing functionality, the connection assembly may comprise a seal sealing the slot, in particular wherein the seal is located in the slot outwards of the contacting element with respect to a depth direction of the slot.

For example, the seal comprises a gasket arranged in a sealing groove provided in the first connection section or in the second connection section.

Embodiments of the invention include that the first structural component is a reflector for electromagnetic radiators and the second structural component is a housing part or vice versa; that the second structural component is a housing part and the first structural component is a cover part for the housing part or vice versa; or that the first structural component and the second structural component are housing parts. Thus, shielded spaces may be provided without generating PIM.

For the above mentioned purpose, further a housing is provided in an embodiment, in particular for an antenna or a mobile communication cell site. The housing comprises a housing part, a cover part and at least one connection assembly as described above. The housing part comprises the second structural component of the connection assembly and the cover part comprises the first structural component of the connection assembly or vice versa.

The features and advantages discussed with respect to the connection assembly also apply to the housing and vice versa.

In an aspect, the housing part has an opening with a plurality of sides, the cover part closes the opening, and a plurality of connection assemblies are provided, wherein the opening is encompassed by the grooves and the connection elements of the connection assemblies, in particular wherein the grooves of the connection assemblies are combined into a single groove encompassing the opening. Thus, the opening can be fully closed without generating PIM.

The number of connection assemblies corresponds in particular at least to the number of sides of the opening.

For example, the connection elements of different connection assemblies, i.e. on different sides of the opening, are separate from one another.

For example, the grooves of two, more than two or all of the connection assemblies may be combined.

Further for the above mentioned purpose, an antenna is provided, in particular for a mobile communication cell site. The antenna comprises a housing as described above and/or at least one connection assembly as described above.

The features and advantages described with respect to the connection assembly and/or the housing also apply to the antenna and vice versa.

For example, the antenna comprises a plurality of electromagnetic radiators and a reflector for the electromagnetic radiators, wherein the reflector comprises the first structural component or the second structural component of the connection assembly. Thus, the signal quality of the antenna is not deteriorated by PIM.

### BRIEF DESCRIPTION OF THE DRAWINGS

Further features and advantages will be apparent from the following description as well as the accompanying drawings, to which reference is made. In the drawings:

FIG. 1 shows a mobile communication cell site with an antenna according to an embodiment of the invention schematically,

FIG. 2 shows a partial schematic perspective view of a connection assembly according to an embodiment of the invention for the antenna according to FIG. 1,

FIG. 3 shows a cross sectional view through the connection assembly of FIG. 2,

FIG. 4 shows a schematic enlarged view of the connection assembly shown at the left hand side of FIG. 3,

FIGS. 5, 6 show schematically a contacting element of the connection assembly of FIG. 4 in a front view and a side view, respectively,

FIG. 7 shows a housing according to an embodiment of the invention having several connection assemblies according to a second embodiment of the invention in a perspective view,

FIG. 8 shows the housing of FIG. 7 in a cross-sectional view,

FIG. 9 shows the connection assembly of the right hand side of FIG. 8 in an enlarged view, and

FIG. 10 shows a view onto the bottom of the cover part of the housing of FIG. 7 schematically.

### DETAILED DESCRIPTION

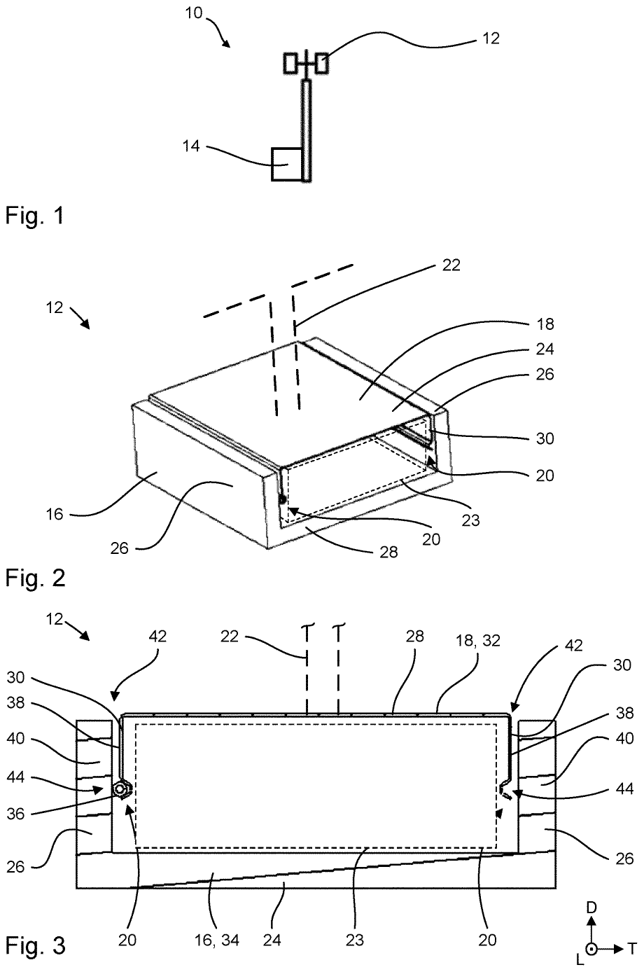

FIG. 1 shows a mobile communication cell site 10 with an antenna 12 according to an embodiment of the invention and base station electronics 14 connected to the antenna 12 for feeding the antenna 12. It is also conceivable that the antenna 12 is an active antenna, i.e. an antenna with an integrated radio and/or other electronics. The antenna 12 may also have active antenna portions and passive antenna portions at the same time.

FIGS. 2 and 3 show parts of the antenna 12 in a perspective view and a cross-sectional view, respectively.

The antenna 12 comprises a housing part 16, a reflector 18, two connection assemblies 20 according to an embodiment of the invention as well as a plurality of electromagnetic radiators 22, of which only one is indicated in dashed lines. Further, the antenna 12 is shown in this embodiment as an active antenna having electronics 23 (shown in dashed lines), e.g. a radio, located in the housing part 16.

The housing part 16 has a U-shaped cross-section with a base 24 and sidewalls 26 extending upwardly from the base 24 with respect to the illustration in FIG. 3.

The reflector 18 also has a U-shaped cross-section with a base 28 and sidewalls 30 extending downwardly from the base 28.

The housing part 16 and the reflector 18 are, for example, made of steel or aluminum, thus having a conductive surface.

The distance between the sidewalls 26 of the housing part 16 is larger than the distance between the sidewalls 30 of the reflector 18.

The reflector 18 is inserted into the housing part 16, and the sidewalls 30 of the reflector 18 extend on the inside of the sidewalls 26 of the housing part 16.

The reflector 18 and the housing part 16 thus enclose a shielded space.

In order to avoid or at least alleviate passive intermodulation (PIM) between the reflector 18 and the housing part 16, the connection assemblies 20 are located at each of the pairs of sidewalls formed by one sidewall 30 of the reflector 18 and one sidewall 26 of the housing part 16.

In the following, with respect to FIG. 3, the left-hand one of the connection assemblies 20 is described. The connection assembly 20 on the right-hand side of FIG. 3 is configured in the same way, but mirrored.

The connection assembly 20 comprises a first structural component 32, a second structural component 34 and a contacting element 36.

Any numerals, like “first” and “second”, are only used for differentiation and do not imply a specific amount or order of components.

In the shown embodiment, the first structural component 32 is the reflector 18 having a first connection section 38 being provided by the respective sidewalls 30 of the reflector 18.

The second structural component 34 is provided by the housing part 16 having a second connection section 40 being the portion of the sidewalls 26 of the housing part 16 adjacent to the sidewalls 30 of the reflector 18.

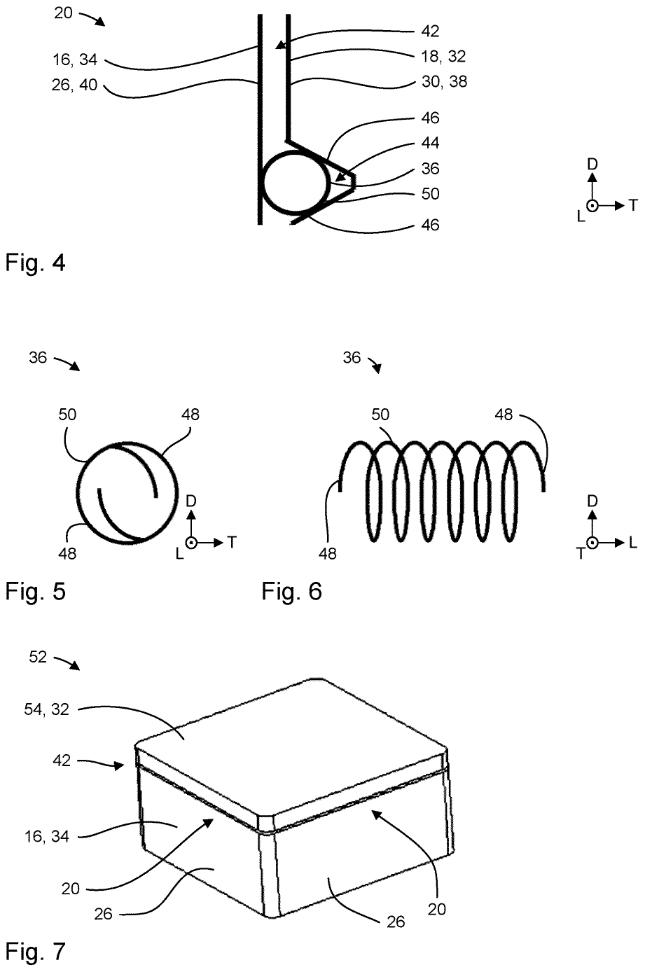

An enlarged and more schematic view of the connection assembly 20 is shown in FIG. 4.

As can be seen, the first and second connection sections 38, 40, i.e. parts of the sidewalls 26, 30, are facing each other and are spaced apart so that a slot 42 is formed in between.

The first connection section 38, i.e. part of the sidewall 30 of the reflector 18 is parallel to the second connection section 40, i.e. part of the sidewall 26 of the housing part 16.

The slot 42 has a depth direction D, a longitudinal direction L and a transverse direction T.

The transverse direction T corresponds to the direction of the shortest connection between the first connection section 38 and the second connection section 40, i.e. in FIG. 3 the transverse direction T is in the horizontal direction.

The depth direction D is perpendicular to the transverse direction T and corresponds, in the shown embodiment, to the direction of the shortest connection between the base 28 of the reflector 18 and the base 24 of the housing part 16, i.e. in FIG. 3 the depth direction D is in the vertical direction.

The longitudinal direction L is perpendicular to the transverse direction T and perpendicular to the depth direction D, i.e. in FIG. 3 the longitudinal direction L extends out of the drawing plane.

In the depth direction D, the slot 42 has an outer side or outer end, being the end of the slot 42 further away from the space enclosed by the two structural components 32, 34. Likewise, the slot 42 has an inner side or inner end, being the end open to or towards the space confined by the two structural components 32, 34.

In the shown embodiment, with respect to FIG. 3, the inner end of the slot 42 is the lower end and the outer end of the slot 42 is the upper end.

A groove 44 is provided in the first connection section 38 of the first structural component 32.

The groove 44 extends in the longitudinal direction L and is open in the transverse direction T towards the second connection section 40 into the slot 42.

The groove 44 is confined by two straight walls 46 of the first structural component 32, wherein the straight walls 46 extend in an angle between 0° and 90° with respect to one another. In particular, the straight walls 46 are not parallel to each other.

As seen in the cross-section of FIG. 4, the groove 44 is V-shaped in the illustrated embodiment.

In the groove 44 and in the slot 42, the contacting element 36 is provided. The contacting element 36 is shown in FIGS. 5 and 6.

The contacting element 36 comprises two end portions 48 and a contacting portion 50 located between the end portions 48.

The contacting portion 50 is a helix in the longitudinal direction L, meaning that the axis of the helix extends in the longitudinal direction L.

The pitch and the radius of the helix is constant. It is also conceivable that the pitch and/or the radius of the helix varies.

In the shown embodiment, the pitch of the helix is smaller than one quarter of the wavelength of the design frequency of the connection assembly 20.

The design frequency of the connection assembly is the frequency or the average frequency of a frequency band for which PIM is going to be avoided or alleviated. This is typically the frequency or average frequency of a frequency band in which the antenna 12 operates.

Further, the contacting portion 50 and in particular the whole contacting element 36 is radially elastic so that it may be compressed.

As best seen in FIG. 5, the end portions 48 extend from the contacting portion 50 radially inwards either curved as shown in FIG. 5, as a straight line or in any other shape.

The contacting element 36 is made of a single piece in the shown embodiment, in particular a wire. The end portions 48 merge into the contacting portion 50 on either side of the contacting portion 50.

The contacting element 36 has a surface made of an electrically conductive material, in particular aluminum, brass, silver, tin, copper and/or bronze. In the shown embodiment, the contacting element 36 is made fully of the conductive material, for example bronze.

It is also conceivable that the contacting element 36, in particular the contacting portion 50 has an electrically conductive surface, for example a surface coating of one or more electrically conducting materials as listed above. In this case, the core of the contacting element 36 may be made of steel.

In the assembled state, as best seen in FIG. 4, the contacting portion 50 extends partly in the groove 44 and partly in the slot 42. In the groove 44, the contacting portion 50 is in physical contact with the straight walls 46 of the first structural component 32.

Due to the curvature of the helix of the contacting portion 50 the physical contact between the contacting portion 50 and the respective straight walls 46 is a single point per turn of the helix.

Likewise, in the slot 42, the contacting portion 50 has physical contact with the second connection section 40 of the second structural component 34. Again, due to the curvature of the contacting portion 50, per turn of the helix the contacting portion 50 contacts the second structural component 34 in a single point.

The remaining parts of the contacting portion 50 and the end portions 48 are well distanced from the straight walls 46 or from the second connection section 40.

Thus, the contacting portion 50 has physical contact only via the very well defined contact points. Due to the radial elasticity of the contacting element 36, the contacting portion 50 is biased against the respective connection section 38, 40, further improving the quality of the contact.

Therefore, the first and second structural components 32, 34 are electrically connected to each other only via the contact points which are very well defined and do not lead to PIM.

The connection assembly therefore allows a connection between the two structural components 32, 34, i.e. in the shown embodiment the reflector 18 with the holding part 16, that avoids or alleviates PIM.

FIGS. 7 to 10 show further embodiments of the invention that correspond substantially to the first embodiment shown above. Thus, in the following, only the differences are discussed and the same and functionally the same components are labeled with the same reference signs.

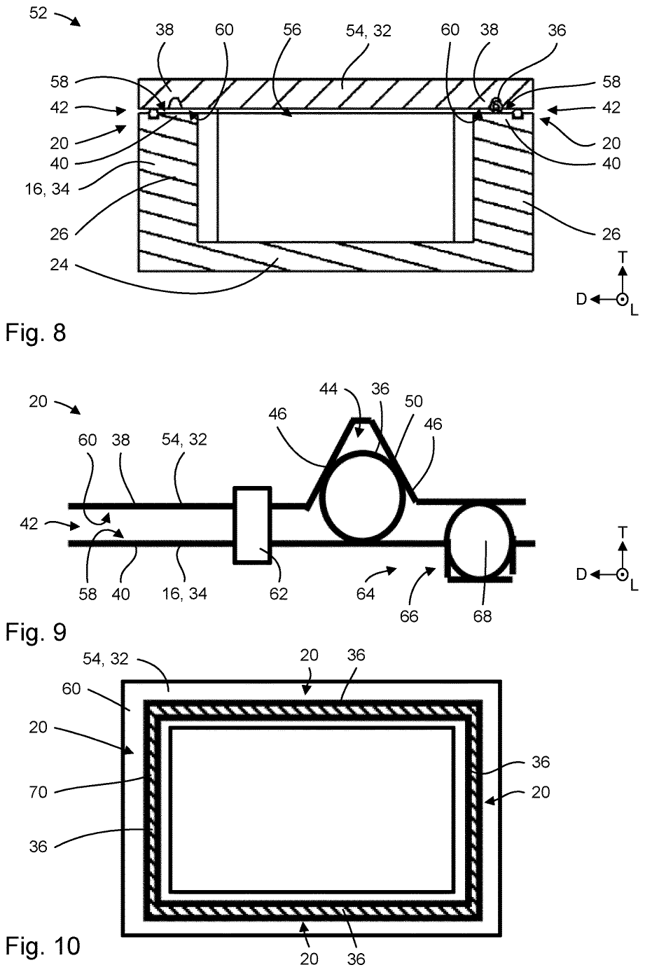

FIGS. 7 and 8 show a housing 52 according to an embodiment of the invention comprising several connection assemblies 20 according to the invention.

The housing 52 may be a housing of the antenna 12 or a housing for the electronics 14 of the cell site 10.

The housing 52 comprises a housing part 16 and a cover part 54.

Similar to the first embodiment, the housing part 16 has a U-shaped cross-section and an opening 56 at its upper end.

In the shown embodiment, the housing 52 has a top surface 58 at the top of the sidewalls 26 defining and surrounding the opening 56.

The cover part 54 is sized to close the opening 56 and may be made of the same material as the housing part 16.

The cover part 54 has a bottom surface 60 corresponding in shape to the top surface 56.

The cover part 54 is the first structural component 32 with the region of the bottom surface 60 being the first connection section 38.

Accordingly, the housing part 16 is the second structural component 34, the region of the sidewalls 26 at the top surface 58 providing the second connection section 40.

FIG. 9 shows an enlarged view of the right-hand side connection assembly 20 of FIG. 8.

As can be seen, the slot 42 extends between the top surface 58 and the bottom surface 60, in particular horizontally.

The contacting element 36 is configured and placed in the slot 42 and the groove 44 as described with respect to the first embodiment.

In the slot 42, a fixation 62 is present further inwards of the contacting element 36 with respect to the depth direction D.

A seal 64 is provided in the slot 42 further outwards of the contacting element 36 with respect to the depth direction D.

The fixation 62 extends transversely through the slot 42 and at least partially through the first and second structural component 32, 34.

The fixation 62 may be a screw connection or a bolted connection in order to mechanically fixate the first structural component 32 to the second structural component 34 or vice versa.

The seal 64 comprises a sealing groove 66 provided in the top surface 58 of the sidewall 26 of the housing part 16.

Thus, in the shown embodiment, the sealing groove 66 is located in the second connection section 40. The sealing groove 66 may as well be located in the bottom side 60 of the cover part 54, i.e. the first connection section 38.

A gasket 68 of the seal 64 is fixed in the sealing groove 66 and extends transversely through the slot. The gasket 68 is, for example, made of rubber and has physical contact with the bottom surface 60 of the cover part 54, i.e. the first structural component 32.

The seal 64 thus provides protection for the inner side of the slot 42 and for the space enclosed by the structural components 32, 34 against environmental influences, in particular dust, water or the like.

FIG. 10 shows a top view of the housing part 16, wherein the fixation 62 and the seal 64 are omitted for simplification.

As can be seen, the opening 56 is rectangular and has four sides. At each of the sides, one of the connections assemblies 20 (indicated by the hatched area) is provided when the cover part 54 is attached to the housing part 16.

Each of the connection assemblies 20 has a separate contacting element 36, and the contacting elements 36 encompass the opening 56 together.

Further, the grooves 44 of the connection assemblies 20 encompass the opening 56 fully. In the shown embodiment, a single groove 70 around the opening 56 is provided meaning that the grooves 44 of the connection assemblies 20 are combined into the single groove 70.

It is conceivable that the opening 56 has a geometry different from a rectangle. In this case, the number of connection assemblies 20 and with that the number of groups combined to a single groove corresponds at least to the number of sides of the opening 56.

Even though a housing part 16 with a cover part 54 has been described, the cover part 54 may as well be another housing part.

In addition, the groove 44 may be arranged on either one of the reflector 18, the housing part 16 or the cover part 54.

Further, the features of the described embodiments may be combined freely. In particular, a seal 64 and/or a fixation 62 may be provided in the first embodiment.

1. A connection assembly for avoiding or alleviating passive intermodulation of connected structural components, having a first structural component, a second structural component and a contacting element for providing a galvanic connection between the first structural component and the second structural component;
wherein the first structural component comprises a first connection section and the second structural component comprises a second connection section, the first connection section and the second connection section facing each other, forming a slot between them;
wherein the first structural component comprises a groove in the first connection section open towards the second connection section, wherein the groove extends in a longitudinal direction of the slot and is confined at least by two straight walls; and
wherein the contacting element comprises a contacting portion being a helix, the contacting portion extending in the longitudinal direction of the slot and being in physical contact with the second connection section of the second structural component and in physical contact with the straight walls of the first structural component.

2. The connection assembly according to claim 1, wherein the contacting element, in particular the contacting portion extends partially in the groove and partially in the slot and/or wherein the contacting portion, in particular the helix, is radially elastic.

3. The connection assembly according to claim 1, wherein the pitch of the helix is smaller than one quarter of a wavelength of a design frequency of the connection assembly.

4. The connection assembly according to claim 1, wherein the contacting element has two end portions, wherein the contacting portion is located between the two end portions, wherein the two end portions extend from the contacting portion radially inwards.

5. The connection assembly according to claim 1, wherein the contacting element is made of a single piece, in particular a wire.

6. The connection assembly according to claim 1, wherein the contacting element has a surface made of an electrically conducting material, in particular aluminum, brass, silver, tin, copper and/or bronze.

7. The connection assembly according to claim 1, wherein the first connection section is parallel to the second connection section.

8. The connection assembly according to claim 1, wherein the connection assembly comprises a fixation extending transversely through the slot and fixing the first structural component to the second structural component, in particular wherein the fixation is located inwards of the contacting element with respect to a depth direction of the slot.

9. The connection assembly according to claim 1, wherein the connection assembly comprises a seal sealing the slot, in particular wherein the seal is located in the slot outwards of the contacting element with respect to a depth direction of the slot.

10. The connection assembly according to claim 9, wherein the seal comprises a gasket arranged in a sealing groove provided in the first connection section or in the second connection section.

11. The connection assembly according to claim 1, wherein the first structural component is a reflector for electromagnetic radiators and the second structural component is a housing part or vice versa; that the second structural component is a housing part and the first structural component is a cover part for the housing part or vice versa;
or wherein the first structural component and the second structural component are housing parts.

12. A housing, in particular for an antenna or a mobile communication cell site, comprising a housing part, a cover part and at least one connection assembly for avoiding or alleviating passive intermodulation of connected structural components, having a first structural component, a second structural component and a contacting element for providing a galvanic connection between the first structural component and the second structural component;
wherein the first structural component comprises a first connection section and the second structural component comprises a second connection section, the first connection section and the second connection section facing each other, forming a slot between them;
wherein the first structural component comprises a groove in the first connection section open towards the second connection section, wherein the groove extends in a longitudinal direction of the slot and is confined at least by two straight walls;
wherein the contacting element comprises a contacting portion being a helix, the contacting portion extending in the longitudinal direction of the slot and being in physical contact with the second connection section of the second structural component and in physical contact with the straight walls of the first structural component; and
wherein the housing part comprises the second structural component of the connection assembly and the cover part comprises the first structural component of the connection assembly or vice versa.

13. The housing according to claim 12, wherein the housing part has an opening with a plurality of sides, the cover part closes the opening, and a plurality of connection assemblies are provided, wherein the opening is encompassed by the grooves and the connection elements of the connection assemblies, in particular wherein the grooves of the connection assemblies are combined into a single groove encompassing the opening.

14. An antenna, in particular for a mobile communication cell site, comprising (a) a housing comprising a housing part, a cover part, and at least one connection assembly and/or (b) the at least one connection assembly, the at least one connection assembly being for avoiding or alleviating passive intermodulation of connected structural components and having a first structural component, a second structural component and a contacting element for providing a galvanic connection between the first structural component and the second structural component;
wherein the first structural component comprises a first connection section and the second structural component comprises a second connection section, the first connection section and the second connection section facing each other, forming a slot between them;
wherein the first structural component comprises a groove in the first connection section open towards the second connection section, wherein the groove extends in a longitudinal direction of the slot and is confined at least by two straight walls; and
wherein the contacting element comprises a contacting portion being a helix, the contacting portion extending in the longitudinal direction of the slot and being in physical contact with the second connection section of the second structural component and in physical contact with the straight walls of the first structural component.

15. The antenna according to claim 14, wherein the antenna comprises a plurality of electromagnetic radiators and a reflector for the electromagnetic radiators, wherein the reflector comprises the first structural component or the second structural component of the connection assembly.
